(19) United States
(12) Patent Application Publication
(10) Pub. No.: US 2024/0194712 A1
(43) Pub. Date: Jun. 13, 2024

(54) SOLID-STATE IMAGING APPARATUS AND ELECTRONIC DEVICE

(71) Applicant: SONY SEMICONDUCTOR SOLUTIONS CORPORATION, Kanagawa (JP)

(72) Inventors: Masashi NAKATA, Kanagawa (JP); Yuichiro BABA, Kanagawa (JP)

(73) Assignee: SONY SEMICONDUCTOR SOLUTIONS CORPORATION, Kanagawa (JP)

(21) Appl. No.: 18/555,043

(22) PCT Filed: Mar. 31, 2022
(86) PCT No.: PCT/JP2022/016843

§ 371 Date: Oct. 12, 2023

Related U.S. Application Data
(60) Provisional application No. 63/185,596, filed on May 7, 2021.

(51) Int. Cl. H01L 27/146

(52) U.S. Cl. CPC H01L 27/14621; H01L 27/14645

(57) ABSTRACT

To acquire multi-spectral information having a narrow half-value width. A solid-state imaging apparatus includes a light receiving element, an optical filter, and a multi-bandpass filter. The light receiving element photoelectrically converts incident light. The optical filter controls a color of the light incident on the light receiving element. The multi-bandpass filter acquires light incident through the optical filter or light incident on the optical filter, in a plurality of frequency bands. The optical filter is a filter corresponding to a plurality of the colors and controls the color incident with respect to each of the light receiving elements. In the multi-bandpass filter, at least one of peaks of a transmitted frequency band has a frequency different from a peak of transmitted light in the filter corresponding to each of the plurality of colors.

### TECHNICAL FIELD

The present disclosure relates to a solid-state imaging apparatus and an electronic device.

### BACKGROUND ART

Many methods exist for acquiring multispectral images, such as a plasmon method and a color filter method, and it is common for the output from a sensor to maintain the spectral curves in these methods.

Also, it is desirable to use a multispectral sensor with a narrow FWHM (Full Width at Half Maximum) because the narrower the FWHM, the better the wavelength analysis performance.

However, from the viewpoint of material development, it is difficult to achieve such wavelength characteristics using only a color filter on the sensor.

### CITATION LIST

### Patent Literature

PTL 1: JP 2016-012746A

### SUMMARY

### Technical Problem

Therefore, the present disclosure provides a solid-state imaging apparatus and an electronic device that acquire multispectral information with a narrow half-value width.

### Solution to Problem

According to one embodiment, the solid-state imaging apparatus includes a light receiving element, an optical filter, and a multi-bandpass filter. The light receiving element photoelectrically converts incident light. The optical filter controls the color of the light incident on the light receiving element. The multi-bandpass filter acquires light incident through the optical filter or light incident on the optical filter, in a plurality of frequency bands. Furthermore, the optical filter is a filter corresponding to a plurality of the colors and controls the color incident with respect to each of the light receiving elements, and in the multi-bandpass filter, at least one of peaks of a transmitted frequency band, has a frequency different from a peak of transmitted light in the filter corresponding to each of the plurality of colors.

The plurality of the colors may have different spectral peak frequencies.

The optical filter may be at least one of a color filter, a plasmon filter, or an organic photoelectric conversion film.

The multi-bandpass filter may have a transmission band with a half-value width narrower than a half-value width of the optical filter corresponding to each of the plurality of colors.

The multi-bandpass filter may be integrally formed in the apparatus by coating, adhesion, or deposition.

The multi-bandpass filter may have a plurality of transmission bands in a transmission frequency band of the optical filter corresponding to each of the plurality of colors.

The light receiving element may output a signal having a plurality of spectral peaks through the multi-bandpass filter.

The light receiving element may be provided with a first light receiving element into which light is incident through the multi-bandpass filter and a second light receiving element into which light is incident without going through the multi-bandpass filter, and may acquire a signal on the basis of an output of the first light receiving element and an output of the second light receiving element.

Spectral estimation may be executed on the basis of the output of the first light receiving element and the output of the second light receiving element.

The multi-bandpass filter may include a first multi-bandpass filter and a second multi-bandpass filter having a transmission band different from that of the first multi-bandpass filter, and the light receiving element may include a third light receiving element into which light is incident through the first multi-bandpass filter, and a fourth light receiving element into which light is incident through the second multi-bandpass filter, and acquire a signal on the basis of an output of the third light receiving element and an output of the fourth light receiving element.

The solid-state imaging apparatus may further include a wavelength extraction circuit that extracts an intensity of light of a predetermined wavelength with respect to a signal output by the light receiving element.

The multi-bandpass filter may include a third multi-bandpass filter and a fourth multi-bandpass filter having a transmission band different from that of the third multi-bandpass filter. Light may be incident on the light receiving element through the third multi-bandpass filter and the fourth multi-bandpass filter so as to have different transmission bands with respect to an image height. The wavelength extraction circuit may execute wavelength extraction using a wavelength extraction parameter for light received from the same target at different image heights.

The wavelength extraction circuit may execute the wavelength extraction by combining a signal acquired through the third multi-bandpass filter and a signal acquired through the fourth multi-bandpass filter.

The wavelength extraction circuit may perform the wavelength extraction on the basis of signals acquired in different frames.

According to one embodiment, the electronic device includes a display and an imaging element. The display displays image information with light emitted by a light emitting element. The imaging element is an imaging element that captures images through the display on an opposite side of a light emitting surface of the display, and includes a light receiving element, an optical filter, and a multi-bandpass. The light receiving element photoelectrically converts incident light. The optical filter controls the color of the light incident on the light receiving element. The multi-bandpass filter acquires light incident through the optical filter or light incident on the optical filter, in a plurality of frequency bands. Furthermore, the optical filter is a filter corresponding to a plurality of the colors and controls the color of the incident light for each of the light receiving elements, and at least one of peaks of a transmitted frequency band of the multi-bandpass filter has a frequency different from a peak of transmitted light in the filter corresponding to each of the plurality of colors.

The electronic device may include, on the inside of the imaging element, a wavelength extraction circuit that extracts an intensity of light of a predetermined wavelength with respect to a signal output by the light receiving element.

The electronic device may include, on the outside of the imaging element, a wavelength extraction circuit that extracts an intensity of light of a predetermined wavelength with respect to a signal output by the light receiving element.

### BRIEF DESCRIPTION OF DRAWINGS

FIG. 1 is a block diagram schematically showing an electronic device according to an embodiment.

FIG. 2 is a diagram showing an example of frequency characteristics of an optical filter and a multi-bandpass filter according to an embodiment.

FIG. 3 is a diagram showing an example of white light spectrum through the optical filter and the multi-bandpass filter according to an embodiment.

FIG. 4 is a diagram showing an example of a result of a matrix operation on an acquired spectrum according to an embodiment.

FIG. 5 is a diagram schematically showing at least a part of a solid-state imaging apparatus according to an embodiment.

FIG. 6 is a diagram schematically showing at least a part of the solid-state imaging apparatus according to an embodiment.

FIG. 7 is a diagram schematically showing at least a part of the solid-state imaging apparatus according to an embodiment.

FIG. 8 is a diagram schematically showing at least a part of the solid-state imaging apparatus according to an embodiment.

FIG. 9 is a diagram schematically showing at least a part of the solid-state imaging apparatus according to an embodiment.

FIG. 10 is a diagram schematically showing at least a part of the solid-state imaging apparatus according to an embodiment.

FIG. 11 is a diagram showing an example of spectral characteristics of a subject.

FIG. 12 is a diagram showing an example of an acquired spectrum according to an embodiment.

FIG. 13 is a diagram showing an example of a spectrum acquired using the multi-bandpass filter according to an embodiment.

FIG. 14 is a diagram showing an example of a spectrum acquired using the multi-bandpass filter according to an embodiment.

FIG. 15 is a diagram schematically showing at least a part of the solid-state imaging apparatus according to an embodiment.

FIG. 16 is a diagram showing an example of a spectrum acquired through the multi-bandpass filter according to an embodiment.

FIG. 17 is a diagram showing an example of a spectrum acquired through the multi-bandpass filter according to an embodiment.

FIG. 18 is a diagram schematically showing an example of an imaging element according to an embodiment.

FIG. 19 is a diagram showing an example of an arrangement of an optical filter according to an embodiment.

FIG. 20 is a diagram showing an example of an arrangement of the optical filter according to an embodiment.

FIG. 21 is a diagram showing an example of an electronic device according to an embodiment.

### DESCRIPTION OF EMBODIMENTS

Embodiments of the present disclosure will be described below with reference to the drawings. The drawings are for illustrative purposes only, and it is not necessary that the shape, size, or ratio of size to other configurations of each part in an actual apparatus be exactly as shown in the drawings. In addition, since the drawings are created in a simplified manner, other configurations necessary for implementation other than those shown in the drawings shall be provided as appropriate.

Although the present disclosure describes, for example, an imaging element for a multispectral camera, it is possible to implement a hyperspectral camera in the same manner. Unless otherwise noted, a half-value width described in the present disclosure refers to full width at half maximum.

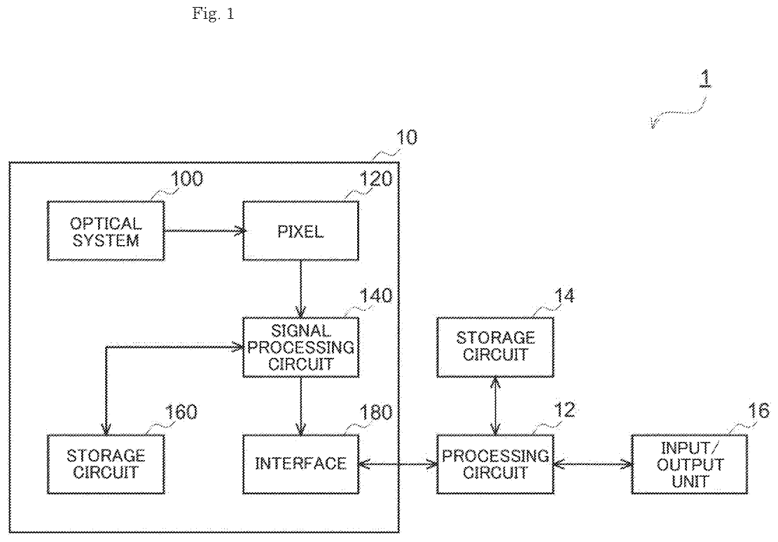

FIG. 1 is a block diagram schematically showing an electronic device according to an embodiment. An electronic device 1 includes a solid-state imaging apparatus 10, a processing circuit 12, a storage circuit 14, and an input/output unit 16. The electronic device 1 may have at least an imaging function, such as a digital still camera with an imaging function, a digital video camera, or a mobile terminal, smartphone, tablet terminal, head-mounted display, and the like with yet another function.

The solid-state imaging apparatus 10 includes an optical system 100, a pixel 120, a signal processing circuit 140, a storage circuit 160, and an interface 180. The solid-state imaging apparatus 10 is a device or module that receives light incident from the outside and acquires and outputs image information or video information (hereinafter simply described as “image information”).

The optical system 100 is an optical system that allows light from the outside to enter a light receiving element appropriately. The optical system 100 is provided with, for example, a lens, an aperture, and the like. As described below, at least a part of an optical filter or at least a part of a multi-bandpass filter may be provided in the optical system 100.

The pixel 120 is provided with a light receiving element and a pixel circuit. The light receiving element acquires and outputs an analog signal based on the intensity of incident light by photoelectric conversion. The light receiving element may be, for example, a photodiode or an organic photoelectric conversion film. The pixel circuit is a circuit that outputs the analog signal, which is output by the light receiving element, at an appropriate timing and at an appropriate magnification. The pixel 120 is a circuit that outputs an analog signal based on the light intensity controlled by the optical system 100.

The signal processing circuit 140 is a circuit that outputs a signal that is output from the pixel 120, after appropriate signal processing. For example, the signal processing circuit 140 may be provided with a DAC (Digital to Analog Converter) that converts an analog signal output from the pixel 120 into a digital signal. The signal processing circuit 140 may also extract wavelength characteristics in the signal output from the pixel 120 or perform image processing on the basis of the acquired signal, as described below.

The storage circuit 160 is a circuit that stores data within the solid-state imaging apparatus 10. The storage circuit 160 may, for example, store digital signals processed by the signal processing circuit 140. The signal processing circuit 140 can write or read data required in the storage circuit 160 at any given timing. If the signal processing circuit 140 is a general-purpose processor and information processing by software is specifically realized using hardware resources, the storage circuit 160 may store data related to this software. The storage circuit 160 may also be connected to the interface 180.

The interface 180 is an interface that outputs signals processed by the signal processing circuit 140 to the outside of solid-state imaging apparatus 10 or accepts input of data including control information from the outside. The format, standard, and the like used for the interface 180 are not particularly limited, and an appropriate interface can be used.

The solid-state imaging apparatus 10 thus appropriately forms and outputs image information on the basis of information from the outside. An imaging method by the solid-state imaging apparatus 10 may be, for example, a rolling shutter method or a global shutter method. The solid-state imaging apparatus 10 may also be compatible with various other imaging methods and various types of image processing.

The processing circuit 12, the storage circuit 14, and the input/output unit 16 are provided separately from the solid-state imaging apparatus 10 in the electronic device 1.

The processing circuit 12 appropriately processes and outputs signals output from the solid-state imaging apparatus 10. Control signals from the outside may also be acquired via the input/output unit 16, and control by the solid-state imaging apparatus 10 may be executed via the interface 180.

The storage circuit 14 forms a storage area outside the solid-state imaging apparatus 10. The processing circuit 12 may write data to or read data from the storage circuit 14 as necessary. If the processing circuit 12 is capable of various types of processing by software, the storage circuit 14 may store programs and the like necessary for this software, as with the storage circuit 160.

The input/output unit 16 is a user interface, and provided with, for example, a display, buttons, a touch panel, and the like. The input/output unit 16 may also be provided with an interface for transferring data to or from the outside. For example, a user may operate the electronic device 1 via the input/output unit 16 to control imaging in the solid-state imaging apparatus 10.

The optical system 100 and the pixel 120 will be described with some non-limiting examples. For example, in the drawings, two to four light receiving elements are shown, but the light receiving elements are arranged in a two-dimensional array, and the drawings show some of these light receiving elements.

In some embodiments, the solid-state imaging apparatus 10 includes a light receiving element that photoelectrically converts incident light, an optical filter (which may include the optical system 100) that controls light incident on the light receiving element, and a multi-bandpass filter that transmits a plurality of frequency bands for light emitted from this optical filter or light incident on the optical filter.

The optical filter is, for example, a filter related to a color incident on the light receiving element, and controls the spectrum of the incident light in association with the color information. The optical filter may be a general color filter or a plasmon filter. An organic photoelectric conversion film may also be used as a concept that combines the optical filter and the light receiving element.

The optical filter may be provided for each light receiving element. In this case, each light receiving element receives light having a predetermined frequency characteristic. Color image reconstruction can be realized by providing optical filters corresponding to a plurality of colors, for different light receiving elements. These optical filters may have different peak frequencies for each color in the spectrum.

In the multi-bandpass filter, at least one of the transmission band peaks has a different frequency from the spectral peaks transmitted by the respective optical filters.

The half-value width of each transmission band of the multi-bandpass filter is narrower than the half-value width of the spectrum of the optical filter corresponding to each color.

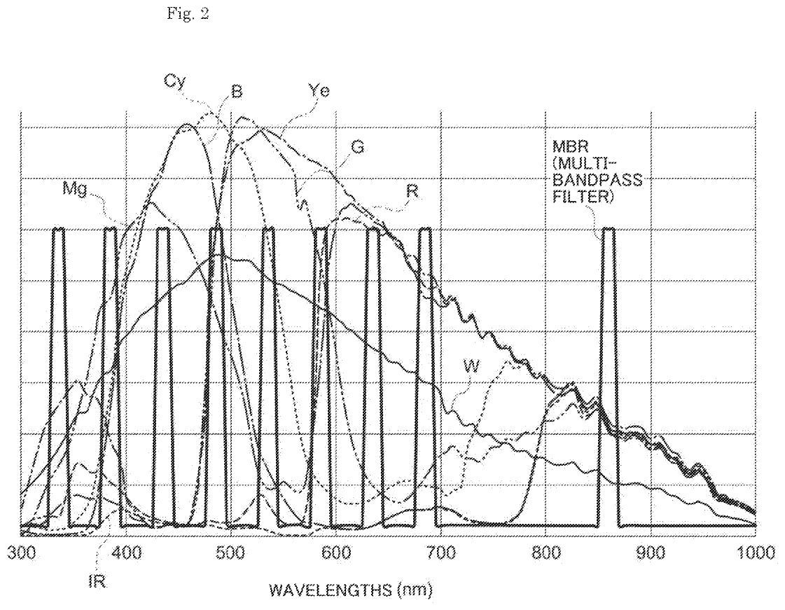

FIG. 2 is a diagram showing an example of the transmission characteristics of the optical filters and the transmission characteristics of the multi-bandpass filter. The optical filters have transmission characteristics that transmit the spectrum for a predetermined color as indicated by R (red), G (green), B (blue), Mg (magenta), Cy (cyan), Ye (yellow), W (white), and IR (infrared), respectively. The optical filters are provided in several types suitable for the solid-state imaging apparatus 10 to function as a multispectral sensor.

On the other hand, an MBP (multi-bandpass filter) has transmission characteristics for a plurality of frequency bands, and at least one band has a peak value frequency that differs from the peak value of the transmission characteristics of each optical filter. The frequency characteristics in each transmission band of the multi-bandpass filter have a half-value width narrower than the half-value width in the frequency characteristics of each optical filter.

As shown in FIG. 2, the multi-bandpass filter may have a plurality of transmission bands in each color frequency band.

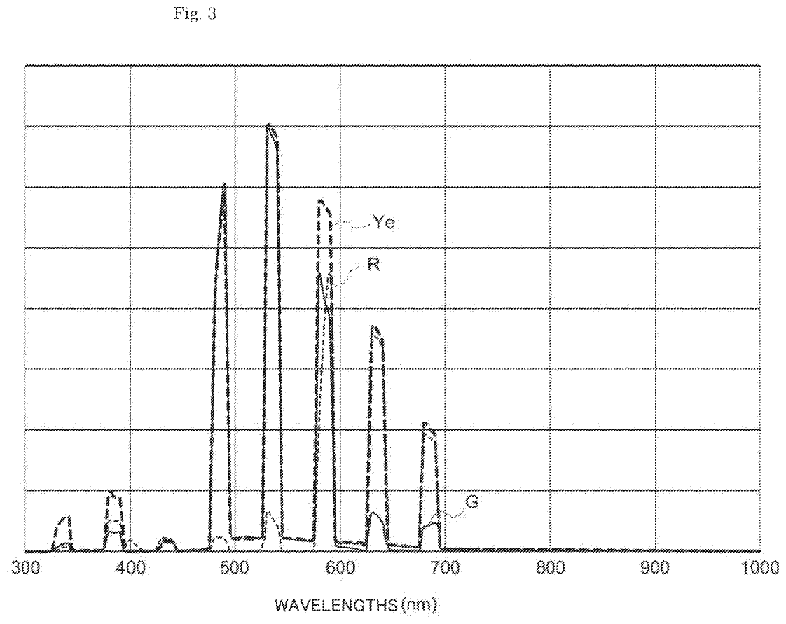

FIG. 3 is a diagram showing an example of a spectrum acquired through the multi-bandpass filter. In FIG. 3, white light is acquired through the optical filters and the multi-bandpass filter. For example, the outputs from the R, G, and Ye optical filters are superimposed to simplify the drawing.

As shown in this drawing, the signal acquired through the multi-bandpass filter is an output with a plurality of frequency peaks per pixel. By adding matrix operations to this result, narrow-band spectral results can be extracted.

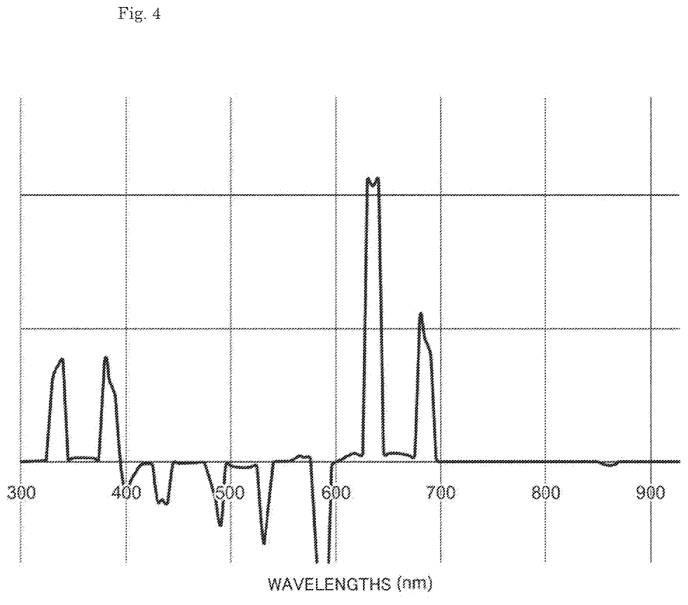

FIG. 4 is a diagram showing an example of a result of a matrix operation. For example, FIG. 4 shows a result of executing matrix operations to acquire a 640 nm spectral result, on a signal acquired through the optical filters and the multi-bandpass filter. For example, in this drawing, the matrix operation is set with 2×(intensity of Ye)−1.15×(intensity of R)−2×(intensity of G), and the spectrum shown in FIG. 3 is the result of the operation.

The color information used in the operation is not limited to these three colors. For example, even if the same 640 nm characteristics are to be acquired, the results of light received through the optical filters corresponding to more colors may be used.

As shown in this drawing, by setting the appropriate matrix operation for the frequency (wavelength) to be acquired and executing operations based on parameters from the signals that are output by the light receiving elements from the light through the optical filters and the multi-bandpass filter, the characteristics of light received from a target at the frequency to be acquired can be acquired.

This operation may be executed by the signal processing circuit 140 inside of the solid-state imaging apparatus 10 or by the processing circuit 12 outside of the solid-state imaging apparatus 10 in FIG. 1. In other words, the operations to extract wavelengths and acquire wavelength characteristics as described above can be executed at an appropriate location inside or outside the solid-state imaging apparatus 10.

The optical filters and the multi-bandpass filter described below are formed according to the filter shown as an example in FIG. 2.

### First Embodiment

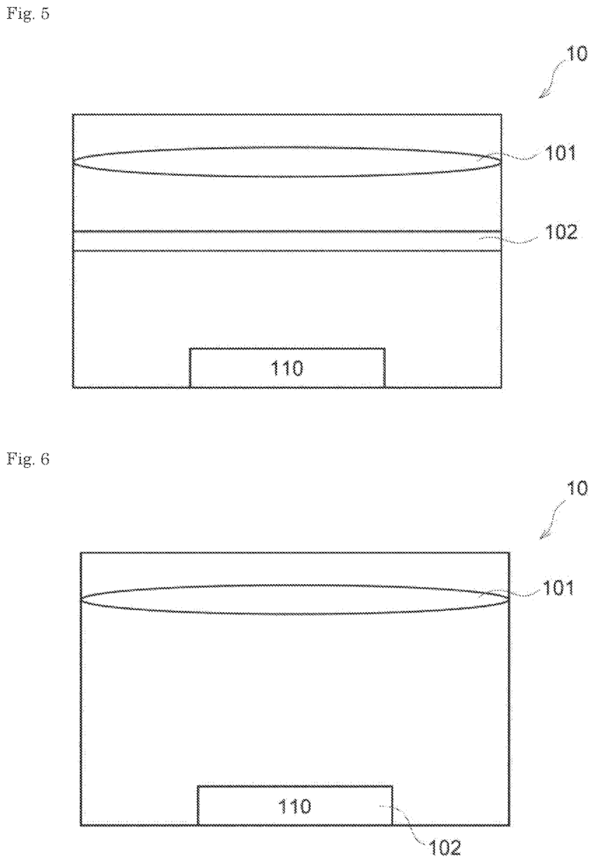

FIG. 5 is a diagram showing an example of the arrangement of the optical filters and imaging element in the solid-state imaging apparatus 10 according to an embodiment. The solid-state imaging apparatus 10 includes a lens 101, a multi-bandpass filter 102, and an imaging element 110.

The imaging element 110 is an element having a plurality of pixels 120. The pixels 120 are arranged in a two-dimensional array in the imaging element 110, and image information is composed on the basis of light information acquired by each pixel. The imaging element 110 may include the pixels 120, the signal processing circuit 140, and the interface 180. The imaging element 110 may also include the storage circuit 160.

The lens 101 is provided as part of the optical system 100. The lens 101 appropriately refracts and diffracts light incident from the outside and propagates the incident light to the pixels 120 provided in the imaging element 110.

The multi-bandpass filter 102 may be formed separately from the imaging element 110 in the solid-state imaging apparatus 10, for example. For example, in the present embodiment, the multi-bandpass filter 102 is arranged between the lens 101 and the imaging element 110. The light incident from the outside is refracted by the lens 101 and then made incident to the imaging element 110 through the multi-bandpass filter 102.

This multi-bandpass filter 102 may be formed, for example, by being coated, bonded, or deposited onto a transparent film in the solid-state imaging apparatus 10. In other words, the method of forming the multi-bandpass filter 102 is not particularly limited as long as the multi-bandpass filter 102 is appropriately arranged.

Thus, in the solid-state imaging apparatus 10, the multi-bandpass filter 102 may be provided outside of the optical system 100 and the imaging element 110, where light is appropriately made incident on the imaging element 110.

### Second Embodiment

FIG. 6 is a diagram showing an example of the arrangement of the optical filters and imaging element in the solid-state imaging apparatus 10 according to an embodiment. The solid-state imaging apparatus 10 may be provided with the multi-bandpass filter 102 inside of the imaging element 110.

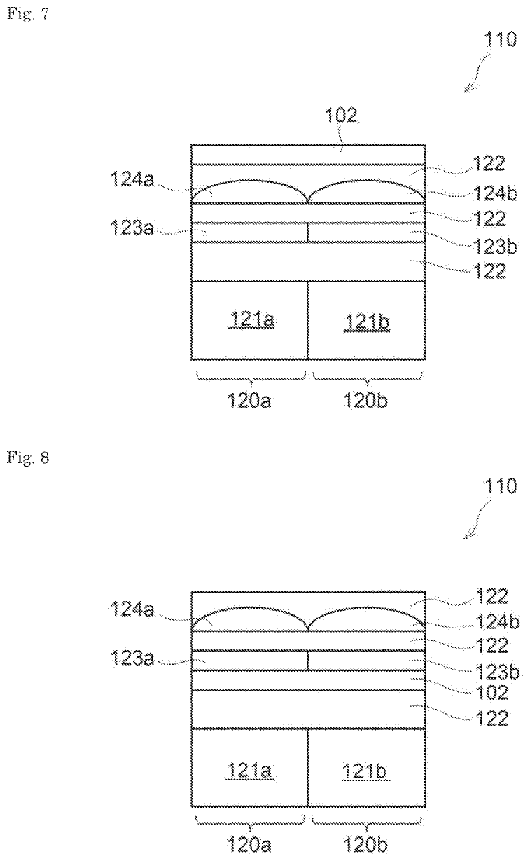

FIG. 7 is a diagram showing an example of providing the multi-bandpass filter 102 in the imaging element 110. In this drawing, for example, two pixels 120, each with one light receiving element, are shown, but the pixels are not limited thereto. The pixels 120 may be configured with one pixel circuit for two light receiving elements as another example, but are not limited to these configurations, as long as it is appropriately configured to acquire information on one color in one light receiving area.

The pixels 120 have a light receiving element 121, a planarization film 122, a color filter 123, and an on-chip lens 124. FIG. 7 shows two pixels 120a, 120b as an example.

The light receiving element 121 is the light receiving element described above and is formed, for example, by a photodiode. The light receiving element 121 converts the received light photoelectrically and outputs an analog signal based on the intensity to the pixel circuit.

The planarization film 122 is formed of a material having transparency in a desirable band (e.g., visible light region+near-infrared region), and is a layer that planarizes the top surface of the light receiving element 121. This planarization film 122 may be formed not only on the top surface of the light receiving element 121, but also on the top surface of the color filter 123 or the top surface of the on-chip lens 124, if necessary.

The color filter 123 is a filter that controls the spectral characteristics of light incident on the light receiving element 121. The color filter 123 is a filter corresponding to the optical filter described above. It is not an essential configuration if the light receiving element 121 is formed by an organic photoelectric conversion film and generates an analog signal with appropriate spectral characteristics for each.

For example, the color filter 123a may be a filter corresponding to R, and the color filter 123b may be a filter corresponding to G. Each light receiving element 121 may be provided with an appropriate color filter 123.

As another example, the color filter 123 may be a plasmon filter. In this case, by appropriately controlling the arrangement, size, and the like of the apertures, light with different characteristics may be transmitted. In addition, the color filter 123 may be in the form of a general color filter mixed with a plasmon filter. By forming the filter in this manner, image information in the visible light region can be acquired, and information on blood flow, blood oxygen concentration, and the like can also be acquired at the same time.

The on-chip lens 124 is a lens for further focusing the light focused on the imaging element 110 by the optical system 100, onto each pixel 120 appropriately. This on-chip lens 124 may be formed as a semiconductor device integrally in the pixels 120 provided with the light receiving elements 121 and the like. In the drawing, the on-chip lens 124 is provided for each light receiving element 121, but one on-chip lens 124 may be provided for a plurality of light receiving elements 121.

The multi-bandpass filter 102 may be provided on the top surface of the on-chip lens 124. In other words, in the present form, light incident on the imaging element 110 through the optical system 100 is transmitted by the multi-bandpass filter 102 in each band, refracted appropriately by the on-chip lens 124, and then made incident on the light receiving element 121 with the spectrum controlled by the color filter 123 in each color.

FIG. 8 is a diagram showing another example in which the imaging element 110 is provided with the multi-bandpass filter 102. As shown in this drawing, the multi-bandpass filter 102 may be arranged at any position between the color filter 123 and the light receiving element 121.

In other words, in the present form, light incident on the imaging element 110 through the optical system 100 is appropriately refracted by the on-chip lens 124, with the spectrum being controlled for each color by the color filter 123, is then transmitted for each band by the multi-bandpass filter 102, and made incident to the light receiving element 121.

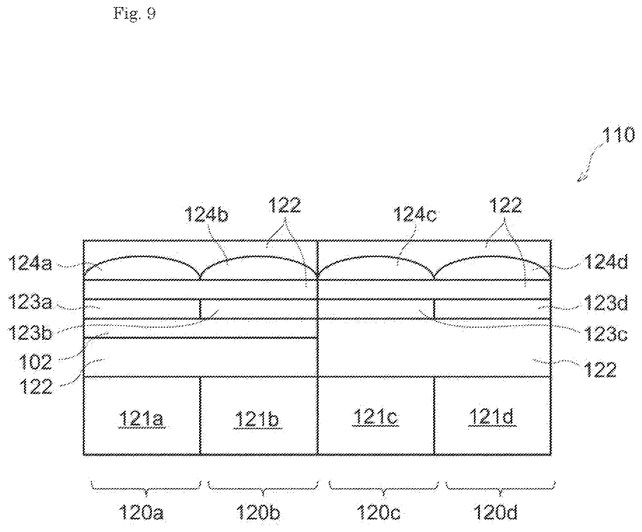

FIG. 9 is a diagram showing another example in which the imaging element 110 is provided with the multi-bandpass filter 102. The pixels 120a, 120b are pixels provided with the multi-bandpass filter 102, and pixels 120c, 120d are pixels without the multi-bandpass filter 102.

In the same imaging element 110, the light receiving element 121 (first light receiving element) in which light enters through the multi-bandpass filter 102 and the light receiving element 121 (second light receiving element) in which light enters without going through the multi-bandpass filter 102 may be mixed together.

The signal processing circuit 140 or the processing circuit 12 shown in FIG. 1 may use the output results of these first and second light receiving elements to acquire wavelength information. Here, the wavelength information is, for example, information indicating spectral characteristics for a certain wavelength. For example, the wavelength information may indicate intensity information at a predetermined wavelength of light reflected or transmitted from a certain target.

The solid-state imaging apparatus 10 or the electronic device 1 may use the output results of these first and second light receiving elements to execute, in particular, spectral estimation. By performing spectral estimation, information about the target can be analyzed in more detail.

The solid-state imaging apparatus 10 may have the first light receiving element and the second light receiving element in one imaging element 110, as shown in this FIG. 9.

As described above, the multi-bandpass filter 102 may be provided in the imaging element 110.

### Third Embodiment

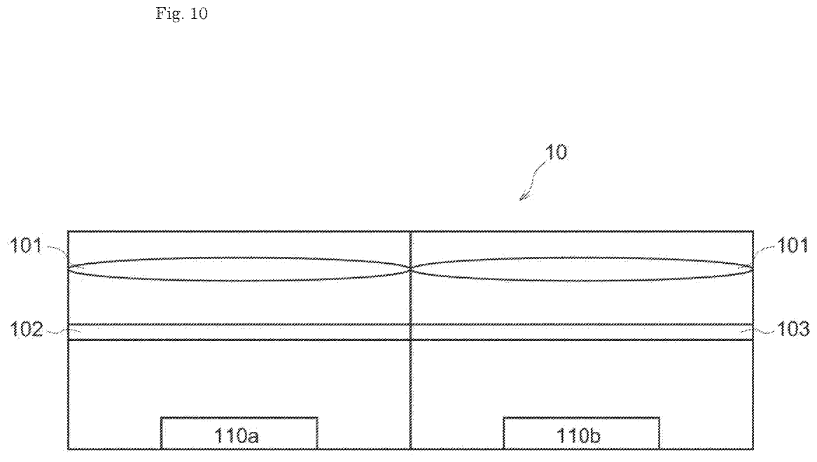

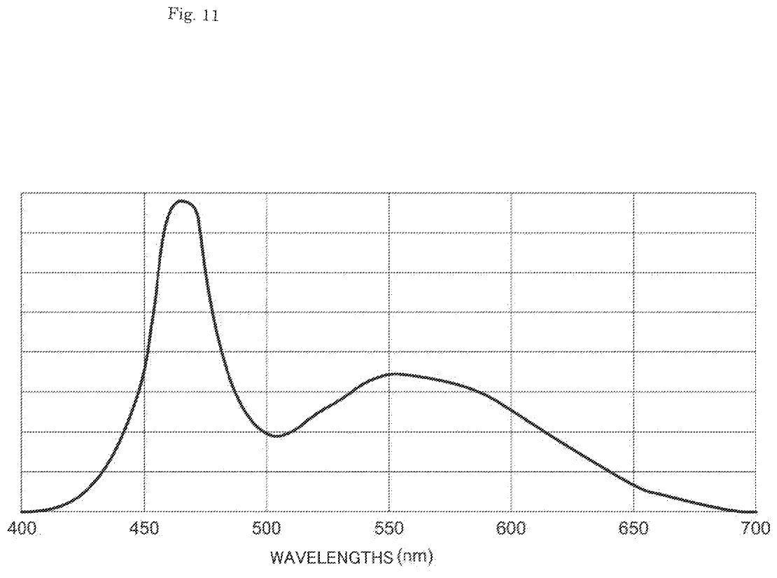

FIG. 10 is a diagram showing an example in which the first light receiving element and the second light receiving element are provided. The solid-state imaging apparatus 10 may have a plurality of imaging elements 110. The solid-state imaging apparatus 10 is provided with, for example, an imaging element 110a and an imaging element 110b.

Light through the lens 101 and the multi-bandpass filter 102 enters the imaging element 110a. On the other hand, light through the lens 101 and a bandpass filter 103 enters the imaging element 110b.

The bandpass filter 103 may be, for example, a filter that transmits light in a visible light band. The bandpass filter 103 may also be, for example, a filter that transmits light in a visible light band and an infrared band.

Thus, the multi-bandpass filter 102 and the bandpass filter 103 can be provided outside of the imaging element 110. In this case, the light receiving element arranged inside of the imaging element 110a operate in the same way as the first light receiving element shown in FIG. 9, and the light receiving element arranged inside of the imaging element 110b operates in the same way as the second light receiving element shown in FIG. 9.

FIG. 9 shows a configuration in which the first and second light receiving elements are provided in one imaging element 110, and FIG. 10 shows a configuration in which the first light receiving element is provided in one imaging element 110 and the second light receiving element is provided in a different imaging element 110. Thus, the first light receiving element and the second light receiving element may be arranged in the same imaging element 110 or in separate imaging elements 110.

By using the configurations shown in FIGS. 9 and 10, data from the acquired information can be interpolated as follows.

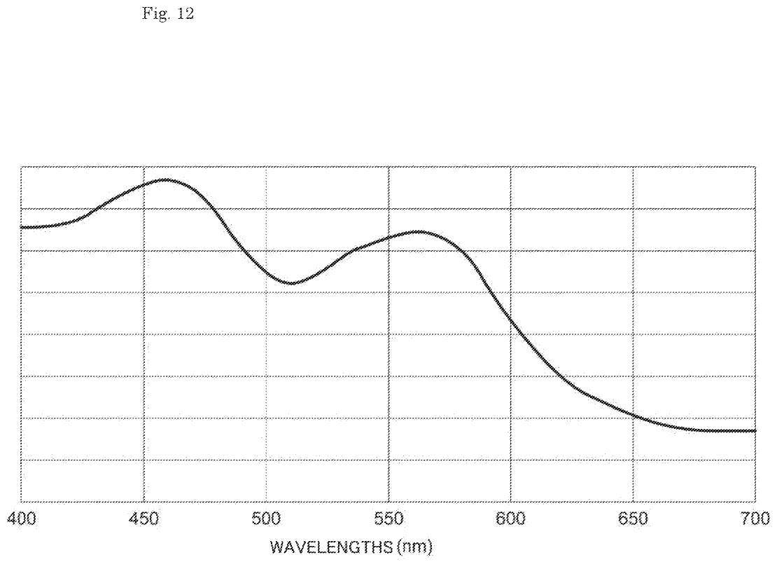

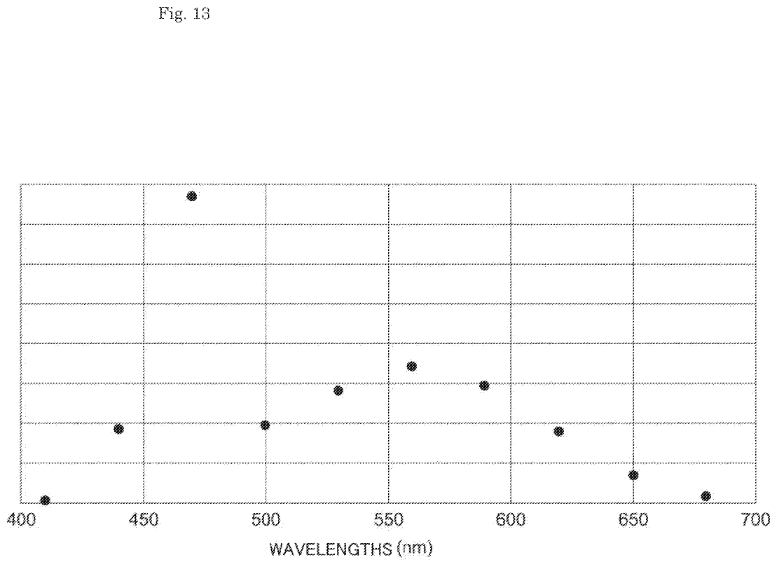

FIG. 11 is a diagram showing an example of spectral characteristics of a subject. The characteristics of this subject imaged through each of the first and second light receiving elements are shown in FIGS. 12 and 13.

FIG. 12 shows, for example, a spectrum reconstructed with the second light receiving element as the light receiving element used for viewing. A sensor used for viewing can acquire information on all wavelengths in visible light and can acquire an image that is close to an image visible to the human eye. On the other hand, the light receiving elements used for viewing are less accurate in estimating the spectrum from the acquired signals than the light receiving elements used for sensing.

FIG. 13 shows, for example, a spectrum extracted with the first light receiving element as the light receiving element used for sensing. Data acquired through the multi-bandpass filter can acquire results that are more accurate than data acquired using the sensor used for band-by-band viewing. On the other hand, when, for example, there are bright spots in the subject, information on such bright spots cannot be extracted, or noise may be generated due to overlap between such bright spots and a band.

The solid-state imaging apparatus 10 or the electronic device 1 in the present embodiment can estimate a continuous spectrum with higher accuracy by combining signals acquired using first and second light receiving pixels through signal processing.

This estimation may be realized by, for example, executing interpolation processing on the band-to-band data acquired using the first light receiving pixel, from the continuous spectrum acquired using the second light receiving pixel. As another example, this estimation may be performed using a learned model that executes the estimation of the continuous spectrum from the information of the multi-bandpass filter and the information of the bandpass filter in the signal processing circuit 140 or the processing circuit 12.

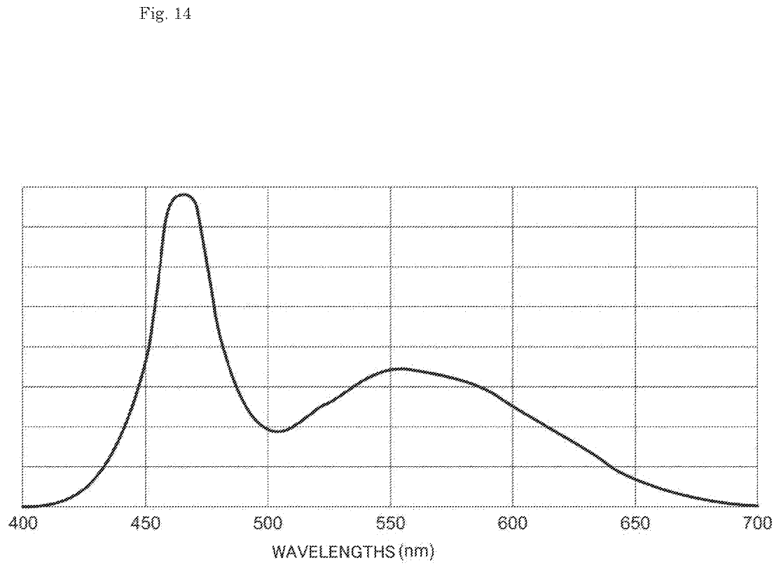

FIG. 14 is a diagram showing an example of the results of the estimation of the synthesized spectrum using the method described above. As shown in this drawing, the results shown in FIGS. 12 and 13 can be used to estimate the spectral characteristics of the subject with greater accuracy than when only FIG. 12 or only FIG. 13 is used.

### Fourth Embodiment

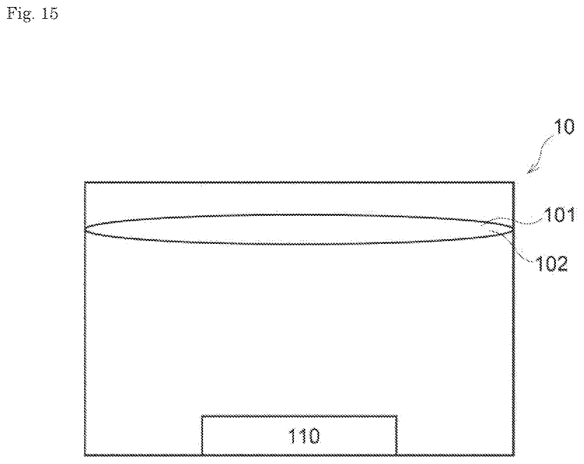

FIG. 15 is a diagram showing another example of the arrangement of the multi-bandpass filter 102. For example, the lens 101 may be generated with a material having the frequency transmission characteristics of the multi-bandpass filter 102. With this configuration, it is possible to control the incident light appropriately by the lens 101 and also to make light having a narrow band spectrum incident onto the imaging element 110.

FIG. 15 shows one lens 101, but the configuration is not limited thereto. For example, a plurality of lenses 101 may be provided, each with or without the characteristics of the multi-bandpass filter 102, and each may have the same functions as in FIGS. 9 and 10 above.

As described above, by using the multi-bandpass filter with a bandwidth narrower than the frequency characteristics of the optical filter, the characteristics in a desired band can be acquired by performing matrix operations. In addition to this, the following effects can also be achieved.

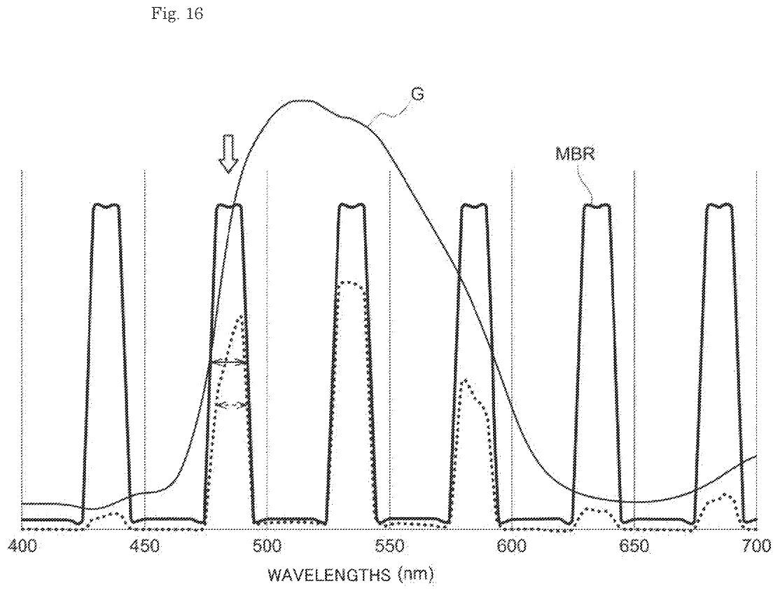

FIG. 16 is a diagram showing the characteristics of a spectrum acquired through the multi-bandpass filter according to one embodiment. FIG. 16 shows, for example, the light corresponding to G. The dashed line shows the spectrum of G light, the solid line shows the transmission frequency characteristics of the multi-bandpass filter, and the dotted line shows the signal received by the light receiving element.

For example, the bands indicated by the arrows are considered. The half-value width of this band of the multi-bandpass filter is the width indicated by the solid arrow. On the other hand, the half-value width of the transmitted G light is the width indicated by the dotted arrow.

For a certain color, the output of the sensor is not constant, but has a shape with a peak. Around the peak, the sensor output decreases. In the band that decreases from the peak, as shown by the band shown by the arrow in FIG. 16, it is possible to acquire spectral information with a narrower half-value width than the band of the multi-bandpass filter itself. This makes it possible to obtain more accurate characteristic values when acquiring spectral characteristics for a single light.

### Fifth Embodiment

In each of the embodiments described above, one type of multi-bandpass filter is used, but the configuration is not limited thereto. The solid-state imaging apparatus 10 can also perform sensing using a plurality of multi-bandpass filters with different characteristics.

For example, multi-bandpass filters with different bandwidths can be used. By using a plurality of types of multi-bandpass filters having different bandwidths, for example, the results of a filter with a narrower bandwidth can be used to acquire the same results as in each of the aforementioned embodiments, and the results of a filter with a wider bandwidth can be used to remove noise and the like by calculation.

As another example, a multi-bandpass filter with different transmission frequency bands itself can be used. For example, the solid-state imaging apparatus 10 may be provided with a third light receiving element that receives light through a first multi-bandpass filter, and a fourth light receiving element that receives light through a second multi-bandpass filter that has a different transmission band from the first multi-bandpass filter. As in the embodiments described above, the third light receiving element and the fourth light receiving element may be mixed in a single imaging element, or the third light receiving element and the fourth light receiving element may be arranged in separate imaging elements.

The signal processing circuit 140 in the solid-state imaging apparatus 10 or the processing circuit 12 outside of the solid-state imaging apparatus 10 can acquire wavelength information on the basis of the results output from the third light receiving element and the fourth light receiving element, respectively.

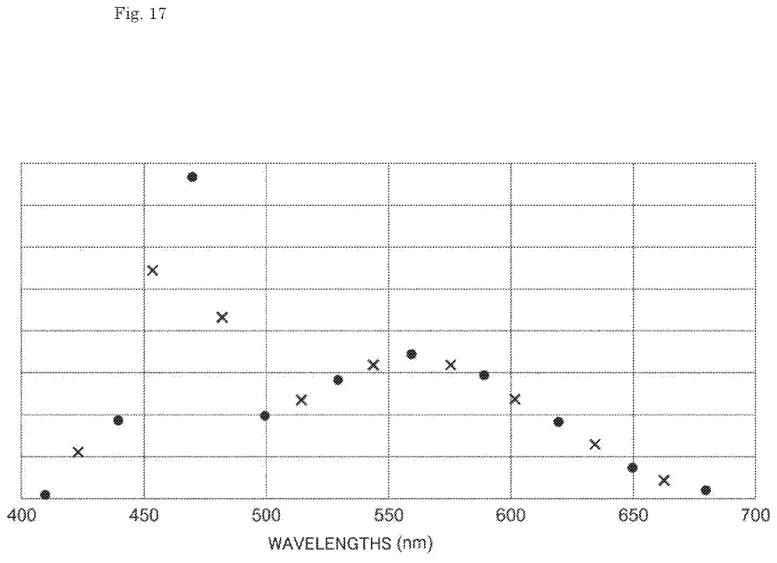

FIG. 17 shows the superimposed spectral characteristics in the case where different multi-bandpass filters are used. ● indicates the result based on the output from the third light receiving element and x indicates the result based on the output from the fourth light receiving element. As shown, it is possible to acquire spectral information in different bands in a state with a certain transmission bandwidth.

For example, by comparing the graph shown in FIG. 13 acquired by the first multi-bandpass filter with the graph shown in FIG. 17 acquired by the first and second multi-bandpass filters, it can be seen that the use of multi-bandpass filters with different characteristics enables more accurate estimation of the spectral characteristics.

### Sixth Embodiment

The fifth embodiment has explained that each light receiving element receives light through a different multi-bandpass filter, but the solid-state imaging apparatus 10 can also be provided with multi-bandpass filters having different characteristics at an even finer granularity.

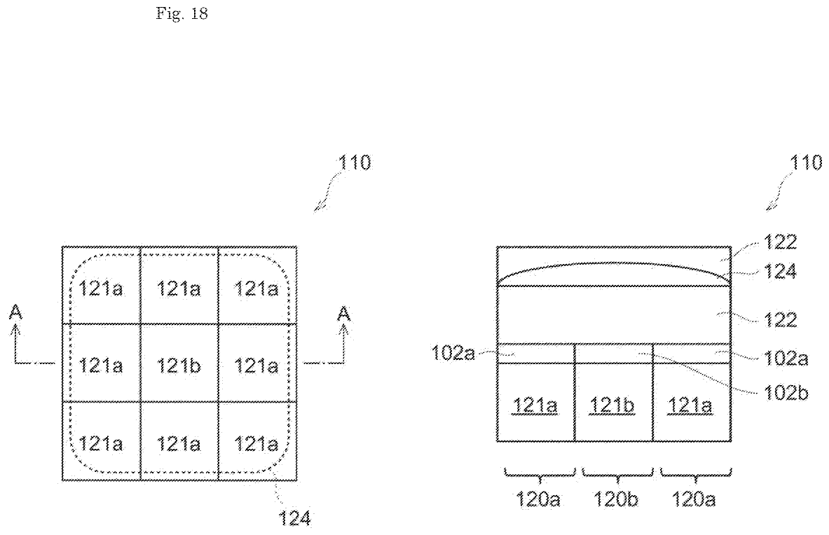

FIG. 18 is a diagram schematically showing the imaging element 110 according to the present embodiment. The left drawing is a plan view, and the right drawing is a cross-sectional view taken along A-A of the left drawing.

For example, as shown in the left drawing, the on-chip lens 124 may be provided on every 3×3 light receiving element 121. Light receiving elements 121a at the periphery and a light receiving element 121b at the center receive light corresponding to images of different image heights from the same position of the target. As shown in the right drawing, the top surface of the light receiving element 121a is provided with a third multi-bandpass filter 102a, and the top surface of the light receiving element 121b is provided with a fourth multi-bandpass filter 102b having different characteristics than the third multi-bandpass filter 102a. The different characteristics may be, for example, having different transmission bands.

The optical filter is not shown in the drawings, but as a non-limiting example, color filters of the same color may be provided in the light receiving elements belonging to the same on-chip lens 124.

By this arrangement, spectral information of light through the multi-bandpass filters having different frequency bands can be acquired by the image heights from the same target.

In this situation, spectral information having different bandwidths can be acquired in accordance with the image height. For example, by superimposing the spectral characteristics for each frame, the spectra of the light received from the same position of the target can be superimposed as shown in FIG. 17. As a result, as in the fifth embodiment described above, it is possible to realize more accurate estimation of spectral information, such as wavelength extraction processing, compared to the case where a single multi-bandpass filter is used.

This can be applied even when there is motion in the target, or when the user grasps the target by hand for sensing, it is possible to acquire the same position information from different image heights due to the user's camera shake. In another example, a piezoelectric element may be provided within the solid-state imaging apparatus 10 to provide minute vibration to the imaging element 110, or a piezoelectric element may be provided within the electronic device 1 to provide minute vibration to the solid-state imaging apparatus 10.

Next, an example of implementation of the color filters will be described.

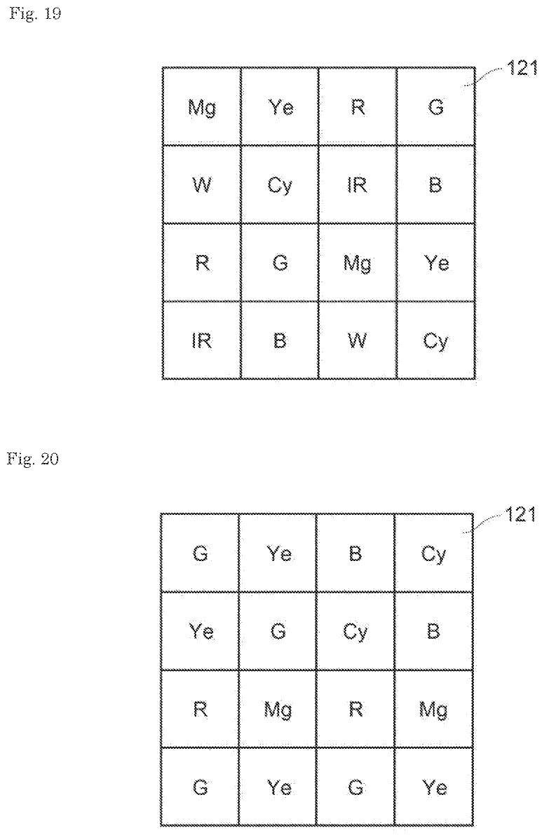

FIG. 19 shows an example of the arrangement of optical filters in light receiving elements according to one embodiment. As shown, filters may be arranged to receive light in the magenta, yellow, cyan, white, red, green, blue, and infrared spectra, respectively.

FIG. 20 is another example of the arrangement of optical filters in light receiving elements according to one embodiment. As shown in this drawing, optical filters may be arranged as a combination of green and yellow, a combination of blue and cyan, and a combination of red and magenta.

In another example, the solid-state imaging apparatus 10 may realize spectral estimation by using the results of both an imaging element including an ALS (Ambient Light Sensor) that photoelectrically converts only specific wavelengths with a restricted wavelength band and a multispectral sensor (preferably four or more colors) that is not missing a wavelength band at least in visible light.

In this form, the solid-state imaging apparatus 10 or the electronic device 1 can acquire information on the intensity of light natural to the human eye from, for example, an illuminance sensor such as ALS, and can acquire information on an image height-dependent spectrum from a multispectral sensor having a multi-bandpass filter. Therefore, by appropriately mixing the outputs from these sensors, it is possible to achieve the effects in each of the embodiments described above and to reconstruct an image that looks more natural to the human eye.

### Implementation Examples

The above has described the form of the solid-state imaging apparatus 10, and some non-limiting implementation examples of the electronic device 1 will be described.

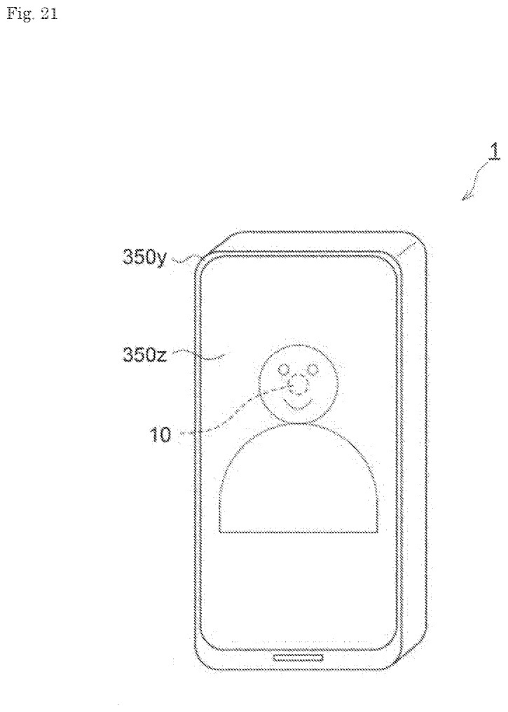

FIG. 21 is a diagram showing an example of implementation of the electronic device 1 using the solid-state imaging apparatus 10 in each of the embodiments described above. The electronic device 1 may be, for example, a smartphone, a tablet terminal, or the like.

The electronic device 1 is provided with, on the opposite side of a display surface of a display, the solid-state imaging apparatus 10 that receives light transmitted through the display. The electronic device 1 has a display surface 350z extending close to the external size of the electronic device 1, and a bezel 350y around the display surface 350z is set to be equal to or less than a few millimeters wide. Normally, the bezel 350y is often equipped with a front camera, but the solid-state imaging apparatus 10 in the present disclosure may be provided in the back part of the display in substantially the center of the display surface, as shown in the dashed line.

This solid-state imaging apparatus 10 can operate as an image sensor that functions as the front camera. Thus, the solid-state imaging apparatus 10 can be provided on the lower side of the display.

Although the form in which one solid-state imaging apparatus 10 is provided is shown, the present invention is not limited thereto, and a plurality of solid-state imaging apparatuses 10 may be provided in different positions on the lower side of the same display.

Thus, the solid-state imaging apparatus 10 may be provided with a display and a solid-state imaging apparatus 10 as an imaging element on the lower side of this display.

The display is provided with a light emitting element and displays image information with light emitted by the light emitting element.

The solid-state imaging apparatus 10 acquires external light through the display, on the opposite side of a light-emitting surface of the display, and performs imaging. As shown in each of the embodiments described above, the solid-state imaging apparatus 10 includes a light receiving element that photoelectrically converts incident light, an optical filter that controls the color of light incident on the light receiving element, and a multi-bandpass filter that acquires light incident through the optical filter or on the optical filter in a plurality of frequency bands.

The optical filter is a filter having a transmission band corresponding to each color for a plurality of color spectra to be acquired, and controls the color incident on each light receiving element.

In the multi-bandpass filter, at least one of the peaks of a transmitted frequency band of the multi-bandpass filter has a frequency different from the peak of transmitted light in the filter corresponding to each of the colors.

As described above, the solid-state imaging apparatus 10 can be provided in smartphones and tablet terminals as an ordinary camera, or the solid-state imaging apparatus 10 of the present disclosure can be provided as an imaging element in devices other than the aforementioned devices.

In each of the embodiments described above, the signal processing circuit 140 or the processing circuit 12 is a general-purpose processor, and in this processor, the intensity of a predetermined wavelength is extracted or the characteristics of a spectrum are acquired, but the present invention is not limited thereto. For example, the electronic device 1 may include a dedicated wavelength extraction circuit inside or outside the solid-state imaging apparatus 10. This wavelength extraction circuit may be an ASIC or may be provided so that wavelength extraction can be performed by software using a general-purpose processor.

The embodiments described above may have the following forms.

(1)

A solid-state imaging apparatus, including:
a light receiving element that photoelectrically converts incident light;
an optical filter that controls a color of light incident on the light receiving element; and
a multi-bandpass filter that acquires light incident through the optical filter or light incident on the optical filter, in a plurality of frequency bands,
wherein
the optical filter is
a filter corresponding to a plurality of the colors and
controls the color incident with respect to each of the light receiving elements, and in the multi-bandpass filter,
at least one of peaks of a transmitted frequency band has a frequency different from a peak of transmitted light in the filter corresponding to each of the plurality of colors.

(2)

The solid-state imaging apparatus according to (1), wherein the plurality of colors have different spectral peak frequencies.

(3)

The solid-state imaging apparatus according to (1) or (2), wherein the optical filter is at least one of a color filter, a plasmon filter, or an organic photoelectric conversion film.

(4)

The solid-state imaging apparatus according to any one of (1) to (3), wherein the multi-bandpass filter has a transmission band with a half-value width narrower than a half-value width of the optical filter corresponding to each of the plurality of colors.

(5)

The solid-state imaging apparatus according to any one of (1) to (4), wherein the multi-bandpass filter is integrally formed in the apparatus by coating, adhesion, or deposition.

(6)

The solid-state imaging apparatus according to any one of (1) to (5), wherein the multi-bandpass filter has a plurality of transmission bands in a transmission frequency band of the optical filter corresponding to each of the plurality of colors.

(7)

The solid-state imaging apparatus according to (6), wherein the light receiving element outputs a signal having a plurality of spectral peaks through the multi-bandpass filter.

(8)

The solid-state imaging apparatus according to any one of (1) to (7), wherein the light receiving element includes:
a first light receiving element into which light is incident through the multi-bandpass filter; and
a second light receiving element into which light is incident without going through the multi-bandpass filter,
the light receiving element acquiring a signal on the basis of an output of the first light receiving element and an output of the second light receiving element.

(9)

The solid-state imaging apparatus according to (8), wherein spectral estimation is executed on the basis of the output of the first light receiving element and the output of the second light receiving element.

(10)

The solid-state imaging apparatus according to any one of (1) to (9), wherein the multi-bandpass filter includes:
a first multi-bandpass filter; and
a second multi-bandpass filter having a transmission band different from that of the first multi-bandpass filter, and
the light receiving element includes:
a third light receiving element into which light is incident through the first multi-bandpass filter; and
a fourth light receiving element into which light is incident through the second multi-bandpass filter, and
acquires a signal on the basis of an output of the third light receiving element and an output of the fourth light receiving element.

(11)

The solid-state imaging apparatus according to any one of (1) to (10), further including a wavelength extraction circuit that extracts an intensity of light of a predetermined wavelength with respect to a signal output by the light receiving element.

(12)

The solid-state imaging apparatus according to (11), wherein the multi-bandpass filter includes:
a third multi-bandpass filter; and
a fourth multi-bandpass filter having a transmission band different from that of the third multi-bandpass filter,
light is made incident on the light receiving element through the third multi-bandpass filter and the fourth multi-bandpass filter so as to have different transmission bands with respect to an image height, and
the wavelength extraction circuit executes wavelength extraction using a wavelength extraction parameter for light received from the same target at different image heights.

(13)

The solid-state imaging apparatus according to (12), wherein the wavelength extraction circuit executes the wavelength extraction by combining a signal acquired through the third multi-bandpass filter and a signal acquired through the fourth multi-bandpass filter.

(14)

The solid-state imaging apparatus according to (12) or (13), wherein the wavelength extraction circuit executes the wavelength extraction on the basis of signals acquired in different frames.

(15)

An electronic device, including:
a display that displays image information with light emitted by a light emitting element; and
an imaging element that captures images through the display on an opposite side of a light emitting surface of the display, and includes:
a light receiving element that photoelectrically converts incident light;
an optical filter that controls a color of light incident on the light receiving element; and
a multi-bandpass filter that acquires light incident through the optical filter or light incident on the optical filter, in a plurality of frequency bands,
wherein
the optical filter is
a filter corresponding to a plurality of the colors and
controls the color incident with respect to each of the light receiving element, and in the multi-bandpass filter,
at least one of peaks of a transmitted frequency band has a frequency different from a peak of transmitted light in the filter corresponding to each of the plurality of colors.

(16)

The electronic device according to (15), including, inside of the imaging element, a wavelength extraction circuit that extracts an intensity of light of a predetermined wavelength with respect to a signal output by the light receiving element.

(17)

The electronic device according to (15), including, outside of the imaging element, a wavelength extraction circuit that extracts an intensity of light of a predetermined wavelength with respect to a signal output by the light receiving element.

The aspects of the present disclosure are not limited to the embodiments described above and include various modifications that are conceivable, and the effects of the present disclosure are not limited to the content described above. Constituent elements of each of the embodiments may be appropriately combined for an application. In other words, various additions, changes, and partial deletions can be performed in a range not departing from the conceptual idea and spirit of the present disclosure derived from content specified in the claims and equivalents thereof.

### REFERENCE SIGNS LIST

1 Electronic device
10 Solid-state imaging apparatus
100 Optical system
101 Lens
102 Multi-bandpass filter
103 Bandpass filter
110 Imaging element
120 Pixel
121 Light receiving element
122 Planarization film
123 Color filter
124 On-chip lens
140 Signal processing circuit
160 Storage circuit
180 Interface
12 Processing circuit
14 Storage circuit
16 Input/output unit

What is claimed is:

1. A solid-state imaging apparatus, comprising:
a light receiving element that photoelectrically converts incident light;
an optical filter that controls a color of light incident on the light receiving element; and
a multi-bandpass filter that acquires light incident through the optical filter or light incident on the optical filter, in a plurality of frequency bands,
wherein
the optical filter is a filter corresponding to a plurality of the colors and controls the color incident with respect to each of the light receiving element, and
in the multi-bandpass filter, at least one of peaks of a transmitted frequency band has a frequency different from a peak of transmitted light in the filter corresponding to each of the plurality of colors.

2. The solid-state imaging apparatus according to claim 1, wherein the plurality of colors have different spectral peak frequencies.

3. The solid-state imaging apparatus according to claim 1, wherein the optical filter is at least one of a color filter, a plasmon filter, or an organic photoelectric conversion film.

4. The solid-state imaging apparatus according to claim 1, wherein the multi-bandpass filter has a transmission band with a half-value width narrower than a half-value width of the optical filter corresponding to each of the plurality of colors.

5. The solid-state imaging apparatus according to claim 1, wherein the multi-bandpass filter is integrally formed in the apparatus by coating, adhesion, or deposition.

6. The solid-state imaging apparatus according to claim 1, wherein the multi-bandpass filter has a plurality of transmission bands in a transmission frequency band of the optical filter corresponding to each of the plurality of colors.

7. The solid-state imaging apparatus according to claim 6, wherein the light receiving element outputs a signal having a plurality of spectral peaks through the multi-bandpass filter.

8. The solid-state imaging apparatus according to claim 1, wherein the light receiving element includes:
a first light receiving element into which light is incident through the multi-bandpass filter; and
a second light receiving element into which light is incident without going through the multi-bandpass filter,
the light receiving element acquiring a signal on the basis of an output of the first light receiving element and an output of the second light receiving element.

9. The solid-state imaging apparatus according to claim 8, wherein spectral estimation is executed on the basis of the output of the first light receiving element and the output of the second light receiving element.

10. The solid-state imaging apparatus according to claim 1, wherein the multi-bandpass filter includes:
a first multi-bandpass filter; and
a second multi-bandpass filter having a transmission band different from that of the first multi-bandpass filter, and
wherein
the light receiving element includes:
a third light receiving element into which light is incident through the first multi-bandpass filter; and
a fourth light receiving element into which light is incident through the second multi-bandpass filter, and
acquires a signal on the basis of an output of the third light receiving element and an output of the fourth light receiving element.

11. The solid-state imaging apparatus according to claim 1, further comprising a wavelength extraction circuit that extracts an intensity of light of a predetermined wavelength with respect to a signal output by the light receiving element.

12. The solid-state imaging apparatus according to claim 11, wherein the multi-bandpass filter includes:
a third multi-bandpass filter; and
a fourth multi-bandpass filter having a transmission band different from that of the third multi-bandpass filter,
wherein
light is made incident on the light receiving element through the third multi-bandpass filter and the fourth multi-bandpass filter so as to have different transmission bands with respect to an image height, and
the wavelength extraction circuit executes wavelength extraction using a wavelength extraction parameter for light received from the same target at different image heights.

13. The solid-state imaging apparatus according to claim 12, wherein the wavelength extraction circuit executes the wavelength extraction by combining a signal acquired through the third multi-bandpass filter and a signal acquired through the fourth multi-bandpass filter.

14. The solid-state imaging apparatus according to claim 12, wherein the wavelength extraction circuit executes the wavelength extraction on the basis of signals acquired in different frames.

15. An electronic device, comprising:
a display that displays image information with light emitted by a light emitting element; and
an imaging element that captures images through the display on an opposite side of a light emitting surface of the display, and includes:
a light receiving element that photoelectrically converts incident light;
an optical filter that controls a color of light incident on the light receiving element; and
a multi-bandpass filter that acquires light incident through the optical filter or light incident on the optical filter, in a plurality of frequency bands,
wherein
the optical filter is
a filter corresponding to a plurality of the colors and controls the color incident with respect to each of the light receiving element, and
in the multi-bandpass filter, at least one of peaks of a transmitted frequency band has a frequency different from a peak of transmitted light in the filter corresponding to each of the plurality of colors.

16. The electronic device according to claim 15, comprising, inside of the imaging element, a wavelength extraction circuit that extracts an intensity of light of a predetermined wavelength with respect to a signal output by the light receiving element.

17. The electronic device according to claim 15, comprising, outside of the imaging element, a wavelength extraction circuit that extracts an intensity of light of a predetermined wavelength with respect to a signal output by the light receiving element.
